(19) United States
(12) Patent Application Publication
(10) Pub. No.: US 2023/0301085 A1
(43) Pub. Date: Sep. 21, 2023

(54) MEMORY DEVICE

(71) Applicant: MACRONIX INTERNATIONAL CO., LTD., Hsinchu (TW)

(72) Inventor: Shih-Hung CHEN, Hsinchu County (TW)

(21) Appl. No.: 17/699,227

(22) Filed: Mar. 21, 2022

(51) Int. Cl. H01L 27/11524; G11C 16/04; H01L 23/528; H01L 23/522; H01L 27/11551; H01L 27/1157; H01L 27/11578; H01L 27/108

(52) U.S. Cl. CPC H01L 27/11524; G11C 16/0483; H01L 23/5283; H01L 23/5226; H01L 27/11551; H01L 27/1157; H01L 27/11578; H01L 27/10805

(57) ABSTRACT

A memory device includes a memory interposer, memory array regions, logic chips, and interconnection lines. The memory array regions are in the memory interposer, in which the memory array regions include at least one memory having NAND architecture. The logic chips are over the memory interposer. The interconnection lines connect the logic chips to each other, and connect the logic chips to the memory array regions.

### BACKGROUND

### Field of Invention

The present invention relates to a memory device.

### Description of Related Art

In recent years, the structure of semiconductor device has changed rapidly, and the storage capacity of semiconductor device increases continuously. Memory device has been widely used in storage device of several products. With the increasing applications, it is desired that memory device has small dimension and large memory capacity. To fulfill the requirement, a memory device having high density and small dimension is needed.

### SUMMARY

According to some embodiments of the present disclosure, a memory device includes a memory interposer, memory array regions, logic chips, and interconnection lines. The memory array regions are in the memory interposer, in which the memory array regions include at least one memory having NAND architecture. The logic chips are over the memory interposer. The interconnection lines connect the logic chips to each other, and connect the logic chips to the memory array regions.

In some embodiments, the memory array regions further includes a volatile memory different from the memory having NAND architecture.

In some embodiments, the volatile memory is a DRAM.

In some embodiments, among the memory array regions, a number of the memory having NAND architecture is greater than a number of the volatile memory.

In some embodiments, the memory device further includes a controller chip over the memory interposer, in which the controller chip is configured to refresh the memory having NAND architecture.

In some embodiments, an endurance of the memory having NAND architecture is in a range from about 10⁶ to about 10¹⁰.

In some embodiments, a retention of the memory having NAND architecture is in a range from 1 second to about 1 year.

In some embodiments, a number of inputs/outputs of the memory having NAND architecture is equal to or greater than 1024.

In some embodiments, each of the logic chips includes about 100 to about 10⁴ cores.

In some embodiments, the memory having NAND architecture includes a bit line, word lines, memory units, and a transistor. The memory units are connected in series, in which the word lines are electrically connected to the memory units, respectively. The transistor connects one of the memory units to the bit line.

According to some embodiments of the present disclosure, a memory device includes a first memory chip and a second memory chip stacked over the first memory chip and electrically connected to the first memory chip. The first and second memory chips each includes a bit line, word lines, memory units, and a transistor. The memory units are connected in series, in which the word lines are electrically connected to the memory units, respectively. The transistor connects one of the memory units to the bit line.

In some embodiments, the second memory chip is stacked over the first memory chip in a staircase manner.

In some embodiments, the memory device further includes a conductive via in contact with a bottom surface of the second memory chip and electrically connected to the second memory chip.

In some embodiments, the memory device further includes a third memory chip stacked over the second memory chip, in which the third memory chip is electrically connected to the first memory chip via through silicon vias vertically extending through the second memory chip.

In some embodiments, the memory device further includes a dielectric layer, a fan-out metal layer, a conductive via, and a bump. The dielectric layer surrounds the first memory chip and the second memory chip. The fan-out metal layer is in contact with a bottom surface of the second memory chip and is electrically connected to the second memory chip, in which the fan-out metal layer laterally extends from the bottom surface of the second memory chip to the dielectric layer. The conductive via is in the dielectric layer and is in contact with a bottom surface of the fan-out metal layer. The bump is disposed on a bottom surface of the dielectric layer and in contact with the conductive via.

In some embodiments, the memory device further includes a third memory chip electrically connected to the first and second memory chips, in which the third memory chip includes a volatile memory.

In some embodiments, the volatile memory is a DRAM.

In some embodiments, an endurance of the first memory chip is in a range from about 10⁶ to about 10¹⁰.

In some embodiments, a retention of the first memory chip is in a range from 1 second to about 1 year.

In some embodiments, a number of inputs/outputs of the first memory chip is equal to or greater than 1024.

It is to be understood that both the foregoing general description and the following detailed description are by examples, and are intended to provide further explanation of the invention as claimed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic view of Deep Leaning Neural Network in accordance with some embodiments of the present disclosure.

FIG. 2 is a circuit diagram of a memory having NAND architecture in accordance with some embodiments of the present disclosure.

FIGS. 3A and 3B are schematic views of a memory device in accordance with some embodiments of the present disclosure, in which FIG. 3B is a cross-sectional view along line B-B of FIG. 3A.

FIG. 4 is a schematic view of a memory device in accordance with some embodiments of the present disclosure.

FIG. 5 is a schematic view of a memory device in accordance with some embodiments of the present disclosure.

FIG. 6 is a schematic view of a memory device in accordance with some embodiments of the present disclosure.

FIGS. 7A and 7B are schematic views of a memory device in accordance with some embodiments of the present disclosure, in which FIG. 7B is a cross-sectional view along line B-B of FIG. 7A.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

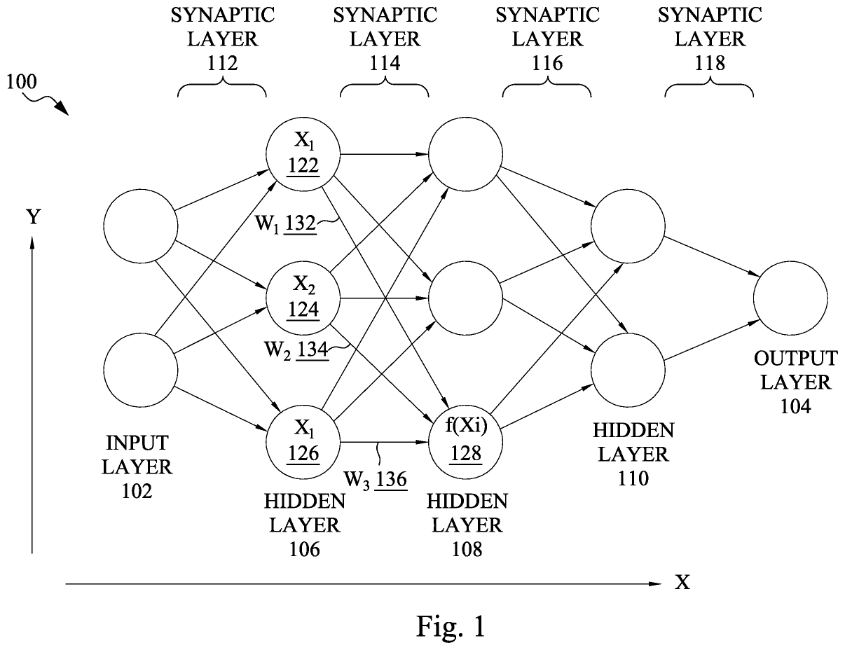

FIG. 1 is a schematic view of Deep Leaning Neural Network in accordance with some embodiments of the present disclosure. A neural network is an information processing paradigm that is inspired by the way biological nervous systems process information. With the availability of large training datasets and sophisticated learning algorithms, neural networks have facilitated major advances in numerous domains such as computer vision, speech recognition, and natural language processing.

The basic unit of computation in a neural network is a neuron. A neuron receives inputs from other neurons, or from an external source and computes an output. FIG. 1 illustrates an example neural network 100. The neural network 100 contains multiple neurons arranged in layers. The neural network 100 includes an input layer 102 of input neurons (i.e., neurons that provide the input data), three hidden layers 106, 108 and 110 of hidden neurons (i.e., neurons that perform computations and transfer information from the input neurons to the output neurons), and an output layer 104 of output neurons (i.e., neurons that provide the output data). Neurons in adjacent layers have synaptic layers of connections between them. For example, the synaptic layer 112 connects neurons in the input layer 102 and the hidden layer 106, the synaptic layer 114 connects neurons in the hidden layers 106 and 108, the synaptic layer 116 connects neurons in the hidden layers 108 and 110, and the synaptic layer 118 connects the neurons in the hidden layer 110 and the output layer 104. All these connections have weights associated with them. For example, the neurons 122, 124 and 126 in the hidden layer 106 are connected to a neuron 128 in the hidden layer 108 by connections with weights w₁ 132, w₂ 134 and w₃136, respectively. The output for the neuron 128 in the hidden layer 108 can be calculated as a function of the inputs (x₁, x₂, and x₃) from the neurons 122, 124 and 126 in the hidden layer 106 and the weights w₁ 132, w₂ 134 and w₃ 136 in the connections. The function can be expressed as follows:

$$f ( {x}_{i} ) = {\sum }_{i = 1}^{M} {w}_{i} {x}_{i}$$

In the sum-of-products expression above, each product term is a product of a variable input xᵢ and a weight wᵢ. The weight wᵢ can vary among the terms, corresponding, for example, to coefficients of the variable inputs xᵢ. Similarly, outputs from the other neurons in the hidden layer can also be calculated. The outputs of the two neurons in the hidden layer 110 act as inputs to the output neuron in the output layer 104.

Neural networks can be used to learn patterns that best represent a large set of data. The hidden layers closer to the input layer learn high level generic patterns, and the hidden layers closer to the output layer learn more data-specific patterns. Training is a phase in which a neural network learns from training data. During training, the connections in the synaptic layers are assigned weights based on the results of the training session. Inference is a stage in which a trained neural network is used to infer/predict input data and produce output data based on the prediction.

In the neural network 100 of FIG. 1, each point and line is a data, and will be stored in a memory. In FIG. 1, the X direction can be regarded as model depth, the Y direction can be regarded as model width, Z direction (not shown) can be regarded as batch size for parallel processing, and thus XYZ can be regarded as requirement of memory.

The purpose of training the neural network is to improve the learning ability of the network. In greater details, neural network calculates a predicted result of an input via forward calculation, and the predicted result is compared with a standard answer. The difference between the predicted result and the standard answer will be sent back to the neural network via backward propagation. The weights of the neural network will be updated according to the difference. Generally, the forward calculation can be regarded as proceeding sum-of-products, layer by layer, along the +X direction of FIG. 1. On the other hand, the backward propagation can be regarded as proceeding complex differential calculation, layer by layer, along the −X direction of FIG. 1.

Once the training is completed, the trained neural network can be applied to a real situation along the X direction of FIG. 1. For example, an inference is performed. Under the situation, the neural network will calculate a predicted result based on the input feature.

After the above operations are completed, the memory data will be changed once or twice. For example, in forward calculation, few memory data will be changed. While in backward propagation, many memory data will be changed.

When the model width (Y) and the batch size (Z) increase, the parallelism will increase. That is, the amount of read/write is large, and thus more time is needed for processing the data.

Moreover, if the model depth (X) increases, the calculation time will increase, and the data will be stored for longer time.

Yet from another aspect, if the model depth (X) and the model width (Y) increase, more memories are needed.

Accordingly, in calculation of neural network, the data will be stored for longer time, it is less needed for latency, and more memories are needed. Volatile memories, such as SRAM, DRAM, are commonly used in conventional working memory. This is because SRAM and DRAM have greater endurance and lower latency. However, SRAM and DRAM have large memory cells, and thus the memory capacity is low, which is not suitable for calculation of big data and artificial intelligence.

To solve the above issue, the present disclosure provides a volatile memory having NAND architecture, which has greater endurance than conventional non-volatile NAND, and is beneficial for calculation of big data and artificial intelligence.

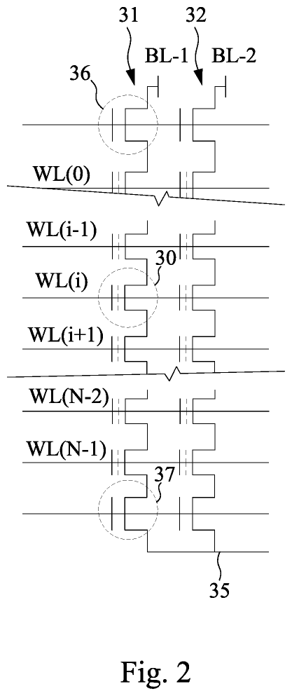

FIG. 2 is a circuit diagram of a memory having NAND architecture in accordance with some embodiments of the present disclosure. In some embodiments, the memory having NAND architecture includes NAND strings 31, 32, in which each of the NAND strings 31, 32 includes several memory units (or memory cells) 30 connected in series. In some embodiments, each memory unit 30 has a structure similar to transistor. Each memory unit may include core memory material. In some embodiments, the core memory material may be charge trapping material, such as SiN, or other suitable materials. In other embodiments, the core memory material can be conductor or doped semiconductor, such as floating gate device.

The memory having NAND architecture also includes word lines WL, which are electrically connected to the memory units 30, respectively. In some embodiments, each word line WL is electrically connected to a gate of a corresponding memory unit 30.

The NAND strings 31, 32 are connected to corresponding bit lines BL-1, BL-2 through respective string select transistors 36, and are connected to common source line 35 through respective ground select transistor.

In a conventional non-volatile NAND memory, the memory unit is small and thus the memory capacity is large. Furthermore, non-volatile NAND memory generally includes high retention, low latency, and poor endurance. Thus, non-volatile NAND memory is commonly used in storage device, such as hard disk (HD).

In the present disclosure, the disclosed memory having NAND architecture has greater endurance by tuning thickness or material of the charge trapping material, or by changing program/erase method. In some embodiments, the endurance of the memory having NAND architecture is in a range from about 10⁶ times to about 10¹⁰ times. In some embodiments, the retention of the memory having NAND architecture is less than the retention of conventional non-volatile NAND memory. For example, the retention of conventional non-volatile NAND memory can be about 10 years, while the retention of the memory having NAND architecture can be about 1 second to about 1 year. In some embodiments, the disclosed memory having NAND architecture may include “volatile” property, and thus a refresh mechanism is needed to maintain the data. Thus, the disclosed memory having NAND architecture may also be referred to as volatile NAND memory. In some embodiments, the number of inputs/outputs of the disclosed memory having NAND architecture is greater than 1024. In some embodiments, the number of inputs/outputs of the disclosed memory having NAND architecture is in a range from about 10³ to about 10⁷. Here, the term “endurance” may indicate the number of times that a memory device can perform the program/erase cycle before it fails to read back the proper data. The term “retention” can be referred to the longest time that a stored data can be maintained in a memory cell.

Based on the above discussion, the disclosed memory having NAND architecture only preserves the advantage of high density as conventional non-volatile NAND memory, but also has greater endurance. Although the disclosed memory having NAND architecture may include poor latency, the calculation of big data and artificial intelligence has less requirement of latency as discussed above. Accordingly, the “volatile” memory having NAND architecture is beneficial for the calculation of big data and artificial intelligence.

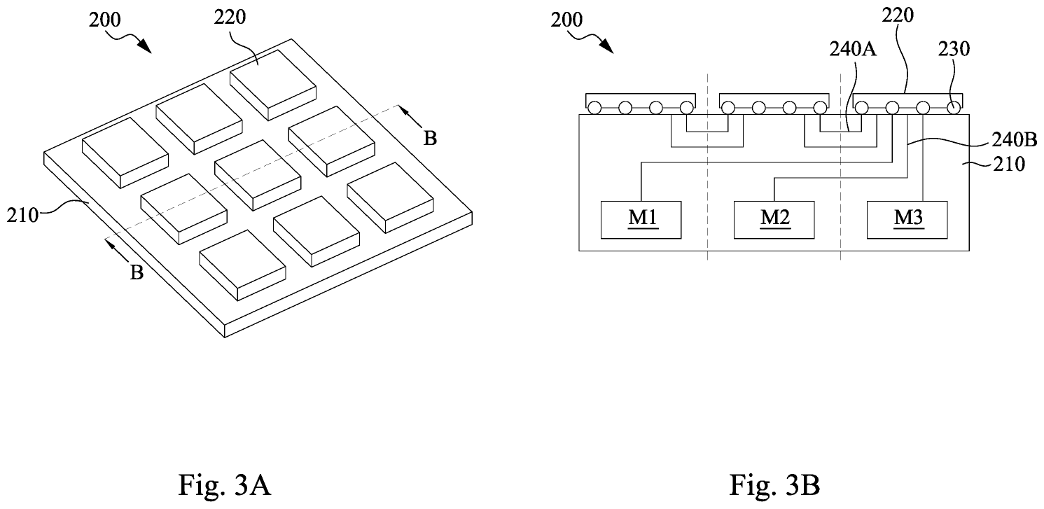

FIGS. 3A and 3B are schematic views of a memory device in accordance with some embodiments of the present disclosure, in which FIG. 3B is a cross-sectional view along line B-B of FIG. 3A. Shown there is a memory device 200 for artificial intelligence, in which the memory device 200 can be sued to conduct the training of a neural network as discussed in FIG. 1.

The memory device 200 includes a memory interposer 210. Here, the memory interposer may indicate using memory as an interposer, which means that the interposer includes memory. In some embodiments, the memory interposer may include one or more memory chips including independent I/O. In some embodiments, the area of the memory interposer 210 may be about 8.5 cm².

The memory interposer 210 includes several memory array regions M1, M2, and M3. Although in the embodiments of FIG. 3B, three memory array regions are illustrated, the present disclosure is not limited thereto. In other embodiments, more or less memory array regions may be employed. The memory array regions M1, M2, and M3 may include the memory having NAND architecture as discussed in FIG. 2. In some embodiments, such memory having NAND architecture can have greater endurance and include “volatile” property. However, the memory array regions M1, M2, and M3 can also include other volatile memories different from the memory having NAND architecture, such as DRAM or SRAM.

In some embodiments, the memory array regions of the memory interposer 210 only include the memory having NAND architecture. For example, all of the memory array regions M1, M2, and M3 include the memory having NAND architecture.

In other embodiments, the memory array regions of the memory interposer 210 can be hybrid memory array regions. That is, the memory interposer 210 can include the volatile memory having NAND architecture and other types of volatile memories (such as DRAM or SRAM). For example, parts of the memory array regions M1, M2, and M3 include the volatile memory having NAND architecture, while other parts of the memory array regions M1, M2, and M3 include other types of volatile memories (such as DRAM or SRAM). However, in the memory interposer 210, the number of the volatile memory having NAND architecture is greater than the number of other types of volatile memories. For example, two of the memory array regions M1, M2, and M3 include the volatile memory having NAND architecture, and one of the memory array regions M1, M2, and M3 include other types of volatile memories (such as DRAM or SRAM).

In some embodiments, the memory having NAND architecture of the memory array regions M1, M2, and M3 can include 2D arrangement as illustrated in FIG. 2. In other embodiments, the memory having NAND architecture of the memory array regions M1, M2, and M3 can include 3D arrangement.

In some embodiments, the retention of the core memory data of each of the memory array regions M1, M2, and M3 is in a range from about 1 second to about 1 year. In some embodiments, the endurance of the memory array regions M1, M2, and M3 can be greater than 10⁶ times. The total inputs/outputs of each of the memory array regions M1, M2, and M3 can be greater than 1024. In some embodiments, the total inputs/outputs of each of the memory array regions M1, M2, and M3 is in a range from about 10³ to about 10⁷.

As mentioned above, because the memory having NAND architecture has “volatile” property, and thus the memory array regions M1, M2, and M3 can include integrated refresh controller. In some embodiments, external refresh controller may be used to refresh the memory array regions M1, M2, and M3.

The memory interposer 210 includes several logic chips 220 stacked over the memory interposer 210. In the embodiments of FIG. 3A, nine logic chips 220 are arranged in matrix over the memory interposer 210. Although, nine logic chips 220 are illustrated in FIG. 3A, the present disclosure is not limited thereto. In other embodiments, more or less logic chips may be employed. In some embodiments, the logic chips 220 include the same logic chips. In other embodiments, the logic chips 220 include different logic chips.

It is understood that, in the generation of big data and artificial intelligence, large amount of small cores are commonly used, by using parallel calculation and deep learning to solve different problems. In some embodiments, each logic chip 220 may include large amount of small cores, for example, each logic chip 220 may include about 100 to about 10⁴ cores. For example, the small cores of the logic chips 220 may include GPU, TPU, extremely small CPU, DPU, APU, or the like.

The logic chips 220 can be electrically connected to the memory interposer 210. As shown in the embodiments of FIG. 3B, the logic chips 220 are electrically connected to the memory interposer 210 through micro bumps 230. In other embodiments, the logic chips 220 are electrically connected to the memory interposer 210 through cu-cu bonding.

The memory interposer 210 may include several interconnection lines, in which the interconnection lines includes interconnection lines 240A connecting the logic chips 220 to each other, and interconnection lines 240B connecting the logic chips 220 to memory array regions M1, M2, and M3. The interconnection lines 240A can be used for communications between logic chips 220, and the interconnection lines 240B can provide the logic chips 220 with accessing memory data from the memory array regions M1, M2, and M3 at different positions.

In some embodiments, the interconnection lines 240A and 240B include at least one conductive line extending laterally, and several conductive vias vertically extending from top surface and/or bottom surface of the lateral conductive line. For example, each interconnection line 240A include a conductive line extending laterally, and conductive vias that extends upwardly from opposite sides of the lateral conductive line, so as to connecting the logic chips 220 over the memory interposer 210 to each other. In some embodiments, the interconnection lines 240A may be electrically connected to the logic chips 220 through bumps 230.

On the other hand, each interconnection line 240B include a conductive line extending laterally, one conductive via that extends upwardly from one side of the lateral conductive line, and another conductive via that extends downwardly from another side of the lateral conductive line, so as to connecting the logic chips 220 down to the memory array regions M1, M2, and M3. In the embodiments of FIG. 3B, take the rightmost logic chip 220 as an example, at least three interconnection lines 240B are electrically connected to the logic chips 220, in which the interconnection lines 240B connecting the logic chip 220 to the memory array region M3 below the logic chip 220, connecting the logic chip 220 to the neighboring memory array region M2, and connecting the logic chip 220 to the far memory array region M1.

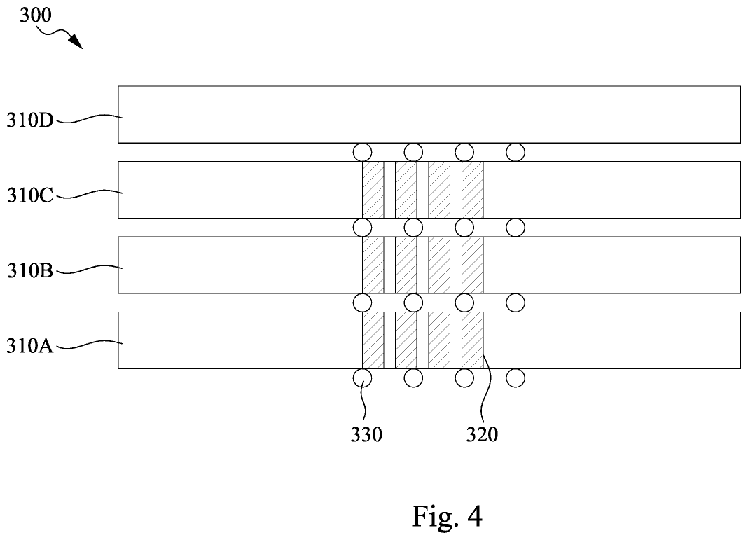

FIG. 4 is a schematic view of a memory device in accordance with some embodiments of the present disclosure. Shown there is a memory device 300 for artificial intelligence, in which the memory device 300 can be sued to conduct the training of a neural network as discussed in FIG. 1.

The memory device 300 includes vertically stacked memory chips 310A, 310B, 310C, and 310D. In the embodiments of FIG. 4, although four memory chips are illustrated, the present disclosure is not limited thereto. In other embodiments, more or less memory chips may be employed. The memory chips 310A, 310B, 310C, and 310D may include the memory having NAND architecture as discussed in FIG. 2. In some embodiments, such memory having NAND architecture can have greater endurance and include “volatile” property. However, the memory chips 310A, 310B, 310C, and 310D can also include other volatile memories different from the memory having NAND architecture, such as DRAM or SRAM.

In some embodiments, the memory chips 310A, 310B, 310C, and 310D only include the memory having NAND architecture. For example, all of the memory chips 310A, 310B, 310C, and 310D include the memory having NAND architecture.

In other embodiments, the memory chips 310A, 310B, 310C, and 310D can be hybrid memory chips. That is, the memory chips 310A, 310B, 310C, and 310D can include the volatile memory having NAND architecture and other types of volatile memories (such as DRAM or SRAM). For example, parts of the memory chips 310A, 310B, 310C, and 310D include the volatile memory having NAND architecture, while other parts of the memory chips 310A, 310B, 310C, and 310D include other types of volatile memories (such as DRAM or SRAM). However, in the memory chips 310A, 310B, 310C, and 310D, the number of the volatile memory having NAND architecture is greater than the number of other types of volatile memories.

In some embodiments, each of the memory chips 310A, 310B, 310C, and 310D include several through silicon vias (TSVs) 320. In some embodiments, the memory chips 310A, 3106, 310C, and 310D can be electrically connected to each other through micro bumps 330. In other embodiments, the memory chips 310A, 310B, 310C, and 310D can be electrically connected to each other through cu-cu bonding. It is beneficial for minimizing the device size by using the through silicon vias (TSVs) 320.

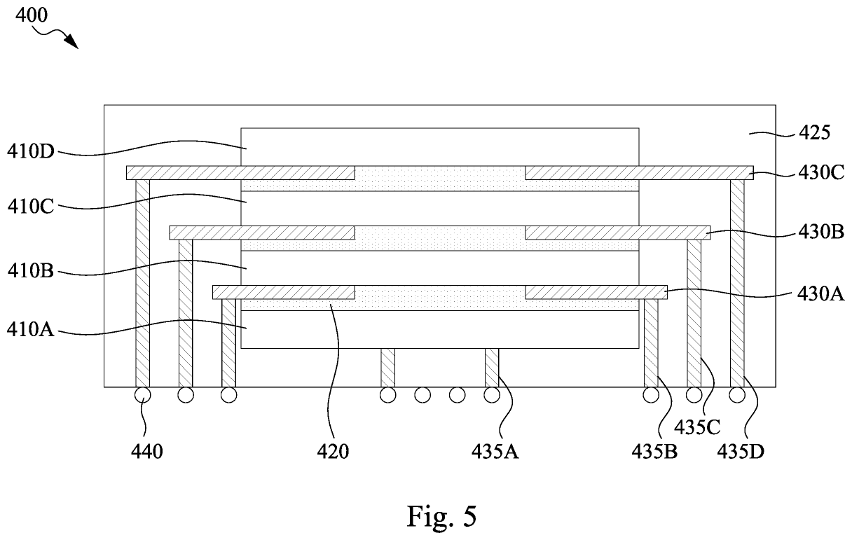

FIG. 5 is a schematic view of a memory device in accordance with some embodiments of the present disclosure. Shown there is a memory device 400 for artificial intelligence, in which the memory device 400 can be sued to conduct the training of a neural network as discussed in FIG. 1.

The memory device 400 includes vertically stacked memory chips 410A, 410B, 410C, and 410D. In the embodiments of FIG. 5, although four memory chips are illustrated, the present disclosure is not limited thereto. In other embodiments, more or less memory chips may be employed. The memory chips 410A, 410B, 410C, and 410D may include the memory having NAND architecture as discussed in FIG. 2. In some embodiments, such memory having NAND architecture can have greater endurance and include “volatile” property. However, the memory chips 410A, 410B, 410C, and 410D can also include other volatile memories different from the memory having NAND architecture, such as DRAM or SRAM.

In some embodiments, the memory chips 410A, 410B, 410C, and 410D only include the memory having NAND architecture. For example, all of the memory chips 410A, 410B, 410C, and 410D include the memory having NAND architecture.

In other embodiments, the memory chips 410A, 410B, 410C, and 4100 can be hybrid memory chips. That is, the memory chips 410A, 410B, 410C, and 410D can include the volatile memory having NAND architecture and other types of volatile memories (such as DRAM or SRAM). For example, parts of the memory chips 410A, 410B, 410C, and 410D include the volatile memory having NAND architecture, while other parts of the memory chips 410A, 410B, 410C, and 410D include other types of volatile memories (such as DRAM or SRAM). However, in the memory chips 410A, 410B, 410C, and 410D, the number of the volatile memory having NAND architecture is greater than the number of other types of volatile memories.

In some embodiments, the memory chips 410A and 4108 are separated from each other through a dielectric layer 420, in which the memory chips 410B and 410C are separated from each other through a dielectric layer 420, the memory chips 410C and 410D are separated from each other through a dielectric layer 420. In some embodiments, the widths of the memory chips 410A, 410B, 410C, and 410D are substantially the same as the widths of the dielectric layers 420.

The memory device 400 includes a dielectric layer 425 that surrounds the memory chips 410A, 410B, 410C, and 410D, and the dielectric layer 420.

The memory device 400 includes fan-out metal layers 430A, 430B, and 430C. In some embodiments, the fan-out metal layer 430A is electrically connected to the memory chip 410B through the bottom surface of the memory chip 410B, and the fan-out metal layer 430A extends laterally from the dielectric layer 420 to the dielectric layer 425. Stated another way, a portion of the fan-out metal layer 430A is in contact with the dielectric layer 420, another portion of the fan-out metal layer 430A is in contact with the dielectric layer 425. Similarly, the fan-out metal layer 430B is electrically connected to the memory chip 410C through the bottom surface of the memory chip 410C, and the fan-out metal layer 430C is electrically connected to the memory chip 410D through the bottom surface of the memory chip 410D. In some embodiments, the fan-out metal layer 430C extends farther than the fan-out metal layer 430B, and the fan-out metal layer 430B extends farther than the fan-out metal layer 430A.

The memory device 400 includes conductive vias 435A, 435B, 435C, and 435D. The conductive via 435A is in contact with the bottom surface of the memory chip 410A, and is electrically connected to the memory chip 410A. The conductive via 435A extends downwardly from the bottom surface of the memory chip 410A to the bottom surface of the dielectric layer 425. On the other hand, the conductive via 435B is in contact with the portion of the fan-out metal layer 430A extending to the dielectric layer 425, and extends downwardly to the bottom surface of the dielectric layer 425. Similarly, the conductive via 435C is in contact with the portion of the fan-out metal layer 430B extending to the dielectric layer 425, and extends downwardly to the bottom surface of the dielectric layer 425. The conductive via 435D is in contact with the portion of the fan-out metal layer 430C extending to the dielectric layer 425, and extends downwardly to the bottom surface of the dielectric layer 425.

The memory device 400 includes micro bumps 440. In some embodiments, the micro bumps 440 are electrically connected to the conductive vias 435A, 435B, 435C, and 435D, respectively. In some embodiments, the micro bumps 440 can be connected to other substrate (not shown), so as to electrically connect the memory chips 410A, 410B, 410C, and 410D to other substrate.

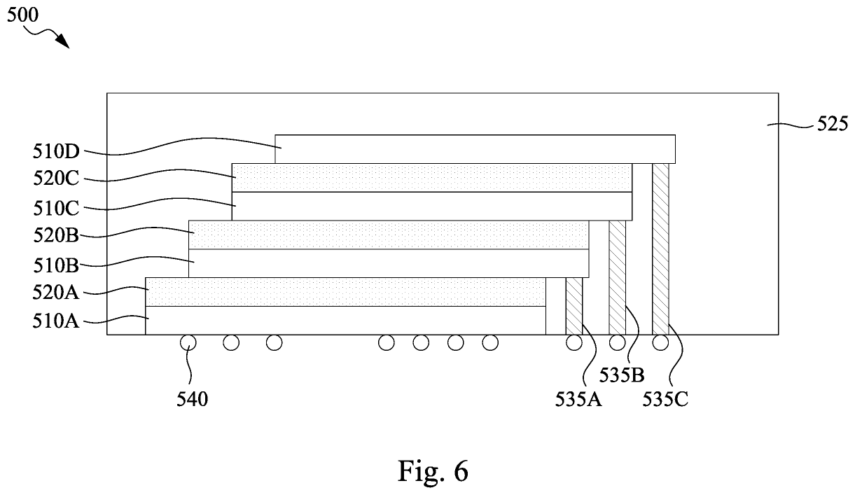

FIG. 6 is a schematic view of a memory device in accordance with some embodiments of the present disclosure. Shown there is a memory device 500 for artificial intelligence, in which the memory device 500 can be sued to conduct the training of a neural network as discussed in FIG. 1.

The memory device 500 includes vertically stacked memory chips 510A, 510B, 510C, and 510D. In the embodiments of FIG. 6, although four memory chips are illustrated, the present disclosure is not limited thereto. In other embodiments, more or less memory chips may be employed. The memory chips 510A, 5108, 510C, and 510D may include the memory having NAND architecture as discussed in FIG. 2. In some embodiments, such memory having NAND architecture can have greater endurance and include “volatile” property. However, the memory chips 510A, 510B, 510C, and 510D can also include other volatile memories different from the memory having NAND architecture, such as DRAM or SRAM.

In some embodiments, the memory chips 510A, 510B, 510C, and 510D only include the memory having NAND architecture. For example, all of the memory chips 510A, 5108, 510C, and 510D include the memory having NAND architecture.

In other embodiments, the memory chips 510A, 510B, 510C, and 510D can be hybrid memory chips. That is, the memory chips 510A, 510B, 510C, and 510D can include the volatile memory having NAND architecture and other types of volatile memories (such as DRAM or SRAM). For example, parts of the memory chips 510A, 510B, 510C, and 510D include the volatile memory having NAND architecture, while other parts of the memory chips 510A, 510B, 510C, and 510D include other types of volatile memories (such as DRAM or SRAM). However, in the memory chips 510A, 510B, 510C, and 510D, the number of the volatile memory having NAND architecture is greater than the number of other types of volatile memories.

In some embodiments, the memory chips 510A, 510B, 510C, and 510D are stacked in a staircase manner. For example, one side of the memory chip 510B extends beyond one side of the memory chip 510A, one side of the memory chip 510C extends beyond one side of the memory chip 5108, and one side of the memory chip 510D extends beyond one side of the memory chip 510C.

The memory device 500 includes dielectric layers 520A, 5208, and 520C. In some embodiments, the memory chips 510A and 510B are separated from each other by the dielectric layer 520A, the memory chips 510B and 510C are separated from each other by the dielectric layer 520b, and memory chips 510C and 510D are separated from each other by the dielectric layer 520C. In some embodiments, the dielectric layer 520A substantially covers the top surface of the memory chip 510A, and has substantially the same width as the memory chip 510A. Similarly, the dielectric layer 520B substantially covers the top surface of the memory chip 510B, and has substantially the same width as the memory chip 510B. The dielectric layer 520C substantially covers the top surface of the memory chip 510C, and has substantially the same width as the memory chip 510C.

The memory device 500 includes a dielectric layer 525 that surrounds the memory chips 510A, 510B, 510C, and 510d, and the dielectric layers 520A, 520B, and 520C. In some embodiments, the bottom surface of the dielectric layer 525 is substantially level with the bottom surface of the memory chip 510A.

The memory device 500 includes conductive vias 535A, 535B, and 535C. The conductive via 535A is in contact with the bottom surface of the memory chip 510B, and is electrically connected to the memory chip 5108. The conductive via 535A extends downwardly from the bottom surface of the memory chip 510B to the bottom surface of the dielectric layer 525. Similarly, the conductive via 535B is in contact with the bottom surface of the memory chip 510C, and is electrically connected to the memory chip 510C. The conductive via 535B extends downwardly from the bottom surface of the memory chip 510C to the bottom surface of the dielectric layer 525. The conductive via 535C is in contact with the bottom surface of the memory chip 510D, and is electrically connected to the memory chip 510D. The conductive via 535C extends downwardly from the bottom surface of the memory chip 510D to the bottom surface of the dielectric layer 525.

The memory device 500 includes micro bumps 540. In some embodiments, the micro bumps 540 are in contact with the bottom surface of the memory chip 510A, and is electrically connected to the memory chip 510A. On the other hand, the micro bumps 540 are electrically connected to the conductive vias 535A, 535B, and 535C. In some embodiments, the micro bumps 540 can be connected to other substrate (not shown), so as to electrically connect the memory chips 510A, 510B, 510C, and 510D to other substrate.

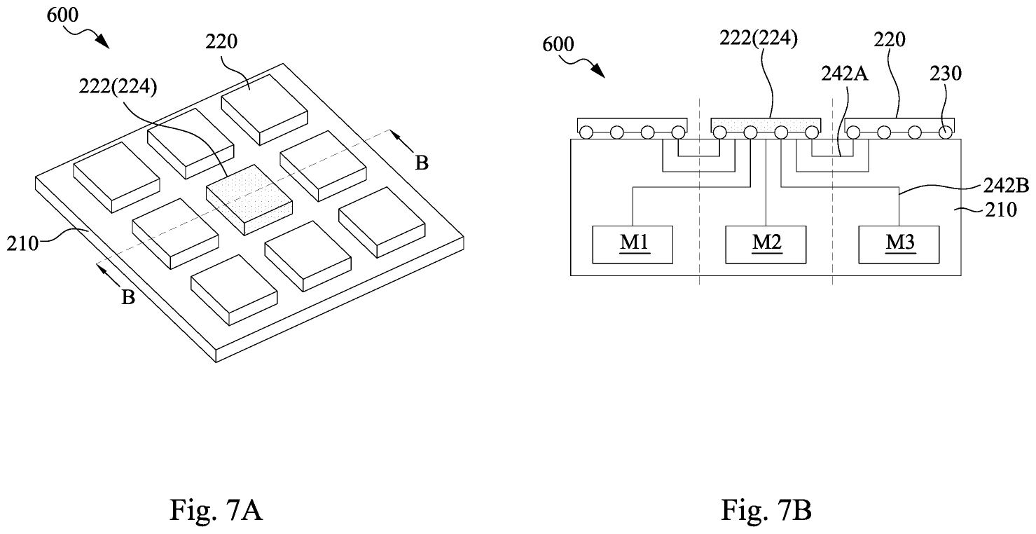

FIGS. 7A and 7B are schematic views of a memory device in accordance with some embodiments of the present disclosure, in which FIG. 7B is a cross-sectional view along line B-B of FIG. 7A. Shown there is a memory device 600 for artificial intelligence, in which the memory device 600 can be sued to conduct the training of a neural network as discussed in FIG. 1. It is noted that some elements of FIGS. 7A and 7B are the same as those discussed in FIGS. 3A and 3B, such elements are labeled the same, and relevant details will not be repeated for brevity.

FIGS. 7A and 7B are different from FIGS. 3A and 3B, in that the memory device 600 further includes a switching matrix chip 222 or a memory controller chip 224 over the memory interposer 210 aside from the logic chips 220 over the memory interposer 210. In FIG. 7A, although only one chip is illustrated in expression of the switching matrix chip 222 or the memory controller chip 224, while the switching matrix chip 222 and the memory controller chip 224 may be two separated chips in some other embodiments. In some embodiments, the memory controller chip 224 can be a controller which can be used to refresh data of the memory having NAND architecture of the memory array regions M1, M2, and M3.

The memory interposer 210 of the memory device 600 may include several interconnection lines, in which the interconnection lines includes interconnection lines 242A connecting the logic chips 220 to the switching matrix chip 222 (or the memory controller chip 224), and interconnection lines 242B connecting the switching matrix chip 222 (or the memory controller chip 224) to the memory array regions M1, M2, and M3. The switching matrix chip 222 (or the memory controller chip 224) is electrically connected to the logic chips 220 through the interconnection lines 242A, so as to operate and switch the logic chips 220, such that the logic chips 220 can be communicated with the memory array regions M1, M2, and M3 at different positions.

In some embodiments, the interconnection lines 242A are similar to the interconnection line 240A discussed in FIG. 3B, in which each interconnection line 242A include a conductive line extending laterally, and conductive vias that extends upwardly from opposite sides of the lateral conductive line, so as to connecting the logic chips 220 over the memory interposer 210 to the switching matrix chip 222 (or the memory controller chip 224). The interconnection lines 242B are similar to the interconnection line 240B discussed in FIG. 3B, in which each interconnection line 242B include a conductive line extending laterally, one conductive via that extends upwardly from one side of the lateral conductive line, and another conductive via that extends downwardly from another side of the lateral conductive line, so as to connecting the switching matrix chip 222 (or the memory controller chip 224) down to the memory array regions M1, M2, and M3.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. In calculation of big data and artificial intelligence parallel calculation and deep learning are commonly used to solve different problems. Thus, large and deep structure needs large memories. Data will be stored for a longer time, and the requirement of the read/write is reduced. On advantage of the disclosure is that a volatile memory having NAND architecture is used in calculation of big data and artificial intelligence, the memory density can be increased, the total inputs/outputs can be increased, and the device performance can be further improved.

What is claimed is:

1. A memory device, comprising:
a memory interposer;
memory array regions in the memory interposer, wherein the memory array regions comprises at least one memory having NAND architecture;
logic chips over the memory interposer; and
interconnection lines connecting the logic chips to each other and connecting the logic chips to the memory array regions.

2. The memory device of claim 1, wherein the memory array regions further comprises a volatile memory different from the memory having NAND architecture.

3. The memory device of claim 2, wherein the volatile memory is a DRAM.

4. The memory device of claim 2, wherein among the memory array regions, a number of the memory having NAND architecture is greater than a number of the volatile memory.

5. The memory device of claim 1, further comprising a controller chip over the memory interposer, wherein the controller chip is configured to refresh the memory having NAND architecture.

6. The memory device of claim 1, wherein an endurance of the memory having NAND architecture is in a range from about 10⁶ to about 10¹⁰.

7. The memory device of claim 6, wherein a retention of the memory having NAND architecture is in a range from 1 second to about 1 year.

8. The memory device of claim 7, wherein a number of inputs/outputs of the memory having NAND architecture is equal to or greater than 1024.

9. The memory device of claim 1, wherein each of the logic chips includes about 100 to about 10⁴ cores.

10. The memory device of claim 1, wherein the memory having NAND architecture comprises:
a bit line;
word lines;
memory units connected in series, wherein the word lines are electrically connected to the memory units, respectively; and
a transistor connecting one of the memory units to the bit line.

11. A memory device, comprising:
a first memory chip; and
a second memory chip stacked over the first memory chip and electrically connected to the first memory chip, wherein the first and second memory chips each comprises:
a bit line;
word lines;
memory units connected in series, wherein the word lines are electrically connected to the memory units, respectively; and
a transistor connecting one of the memory units to the bit line.

12. The memory device of claim 11, wherein the second memory chip is stacked over the first memory chip in a staircase manner.

13. The memory device of claim 12, further comprising a conductive via in contact with a bottom surface of the second memory chip and electrically connected to the second memory chip.

14. The memory device of claim 11, further comprising a third memory chip stacked over the second memory chip, wherein the third memory chip is electrically connected to the first memory chip via through silicon vias vertically extending through the second memory chip.

15. The memory device of claim 11, further comprising:
a dielectric layer surrounding the first memory chip and the second memory chip;
a fan-out metal layer in contact with a bottom surface of the second memory chip and electrically connected to the second memory chip, wherein the fan-out metal layer laterally extends from the bottom surface of the second memory chip to the dielectric layer;
a conductive via in the dielectric layer and in contact with a bottom surface of the fan-out metal layer; and
a bump disposed on a bottom surface of the dielectric layer and in contact with the conductive via.

16. The memory device of claim 11, further comprising a third memory chip electrically connected to the first and second memory chips, wherein the third memory chip comprises a volatile memory.

17. The memory device of claim 16, wherein the volatile memory is a DRAM.

18. The memory device of claim 11, wherein an endurance of the first memory chip is in a range from about 10⁶ to about 10¹⁰.

19. The memory device of claim 18, wherein a retention of the first memory chip is in a range from 1 second to about 1 year.

20. The memory device of claim 19, wherein a number of inputs/outputs of the first memory chip is equal to or greater than 1024.
